(19) United States
(12) Patent Application Publication
(10) Pub. No.: US 2013/0341181 A1
(43) Pub. Date: Dec. 26, 2013

(54) ZINC OXIDE-BASED SPUTTERING TARGET, METHOD OF MANUFACTURING THE SAME, AND THIN-FILM TRANSISTOR HAVING BARRIER LAYER DEPOSITED USING THE SAME

(71) Applicants: SAMSUNG DISPLAY CO., LTD., GYEONGGI-DO (KR); SAMSUNG CORNING PRECISION MATERIALS CO., LTD., GYEONGSANGBUK-DO (KR)

(72) Inventors: JAEWOO PARK, GYEONGGI-DO (KR); DONGJO KIM, CHUNGCHEONGNAM-DO (KR); DO-HYUN KIM, GYEONGGI-DO (KR); WOO-SEOK JEON, GYEONGGI-DO (KR); JUOK PARK, CHUNGCHEONGNAM-DO (KR); INSUNG SOHN, CHUNGCHEONGNAM-DO (KR); SANGWON YOON, CHUNGCHEONGNAM-DO (KR); GUNHYO LEE, CHUNGCHEONGNAM-DO (KR); YONGJIN LEE, CHUNGCHEONGNAM-DO (KR); YOONGYU LEE, CHUNGCHEONGNAM-DO (KR)

(21) Appl. No.: 13/927,754

(22) Filed: Jun. 26, 2013

(30) Foreign Application Priority Data
Jun. 26, 2012 (KR) 10-2012-0068354
Dec. 28, 2012 (KR) 10-2012-0155995

(51) Int. Cl. C23C 14/08; C23C 14/34

(52) U.S. Cl. CPC C23C 14/086; C23C 14/3414; C23C 14/34
USPC 204/192.25; 264/115; 204/298.13

(57) ABSTRACT

A zinc oxide (ZnO)-based sputtering target, a method of manufacturing the same, and a thin-film transistor (TFT) having a barrier layer deposited using the same. The zinc oxide-based sputtering target includes a sinter containing zinc oxide doped with gallium oxide, the content of the gallium oxide ranging, by weight, from 10 to 50 percent of the sinter, and a backing plate bonded to the rear surface of the sinter to support the sinter. The zinc oxide-based sputtering target can be subjected to direct current (DC) sputtering, and improve the contact and etching characteristics of a barrier layer that is deposited using the same.

### CROSS REFERENCE TO RELATED APPLICATION

The present application claims priority from Korean Patent Application Number 10-2012-0068354 and 10-2012-0155995 filed on Jun. 26, 2012 and Dec. 28, 2012, the entire contents of which are incorporated herein for all purposes by this reference.

### BACKGROUND OF THE INVENTION

1. Field of the Invention

The present invention relates to a zinc oxide (ZnO)-based sputtering target, a method of manufacturing the same, and a thin-film transistor (TFT) having a barrier layer deposited using the same, and more particularly, to a zinc oxide-based sputtering target which can be subjected to direct current (DC) sputtering and improve the contact and etching characteristics of a barrier layer that is deposited using the same, a method of manufacturing the same, and a TFT having a barrier layer deposited using the same.

2. Description of Related Art

A liquid crystal display (LCD) or an electroluminescent display (EL) has superior displaying performance and consumes little power. Therefore, an LCD or EL is widely used for display devices of mobile phones, personal computers (PCs), word processors, TVs or the like. These displays operate using transistors, namely, thin-film transistors (TFTs) which are formed of fine patterns. Fine patterns of TFTs are obtained by forming a thin film from different materials using a variety of deposition methods, followed by etching. These fine patterns are divided into gate, source and drain electrodes. While Al, Mo or the like has been used as an electrode material, materials having a higher electrical conductivity are required as displays have a higher definition in order to realize a higher image quality. As an approach, Cu from among metal materials that has a high electrical conductivity and is inexpensive is gaining interest as an electrode material. Research using Cu as the electrode material is being carried out by research organizations and companies.

Since the Cu electrode has superior electrical conductivity, it can realize uniform characteristics when it is thinner than other electrodes. It is therefore possible to reduce the tact time of processing, thereby reducing manufacturing cost. Furthermore, the Cu electrode is applicable to high-specification products which require a high electrical conductivity.

However, Cu of the Cu electrode may diffuse into an upper or lower layer made of other materials or react with such other materials since it has good reactivity. This consequently deteriorates the performance of the TFT, which is problematic. In particular, during deposition of a protective layer that is referred to as passivation on the source and drain electrodes, Cu may be oxidized, thereby deteriorating the contact between Cu and the protective layer. Consequently, the protective layer may peel off or the performance of the TFT may deteriorate, which is problematic.

Accordingly, it is then more important to introduce a barrier layer that can be etched without the addition of a separate process in the etching process of patterning Cu to form the Cu electrode and reduce the diffusion or reaction of Cu into or with another layer.

The information disclosed in the Background of the Invention section is provided only for better understanding of the background of the invention, and should not be taken as an acknowledgment or any form of suggestion that this information forms a prior art that would already be known to a person skilled in the art.

### RELATED ART DOCUMENT

Patent Document 1: Korean Patent Application Publication No. 2010-0107571 (Oct. 6, 2010)

### BRIEF SUMMARY OF THE INVENTION

Various aspects of the present invention provide a zinc oxide (ZnO)-based sputtering target which can be subjected to direct current (DC) sputtering and improve the contact and etching characteristics of a barrier layer that is deposited using the same, a method of manufacturing the same, and a thin-film transistor (TFT) having a barrier layer deposited using the same.

In an aspect of the present invention, provided is a zinc oxide-based sputtering target that includes: a sinter containing zinc oxide doped with gallium oxide, the content of the gallium oxide ranging, by weight, from 10 to 50 percent of the sinter; and a backing plate bonded to the rear surface of the sinter to support the sinter.

According to an embodiment of the present invention, the resistivity of the sputtering target may be 100Ω·cm or less.

The sputtering target may be a target that can be subjected to direct current (DC) sputtering.

The power density that is applied during the DC sputtering may range from 0.1 to 8 W/cm².

The density of the sputtering target may be 5.3 g/cm³ or greater.

Aggregates of the gallium oxide may be distributed at a size of 1 μm or less inside the sinter.

The sinter may include at least one selected from group III elements and group IV elements.

In another aspect of the present invention, provided is a method of manufacturing a thin-film transistor which includes an electrode and an oxide semiconductor layer. The method includes the step of depositing a barrier layer between the electrode and the oxide semiconductor layer using the foregoing zinc oxide-based sputtering target.

According to an embodiment of the present invention, the barrier layer may have a crystal size ranging from 10 to 5000 Å.

The barrier layer may be deposited to a thickness ranging from 30 to 50 nm.

The resistivity of the barrier layer may range from 100 to 1×10⁻⁴Ω·cm.

The electrode may be made of Cu.

In a further aspect of the present invention, provided is a method of manufacturing a zinc oxide-based sputtering target. The method includes the following steps of: preparing a slurry by adding gallium oxide to zinc oxide, the content of the gallium oxide ranging, by weight, from 10 to 50 percent of the slurry; forming a granular powder by drying the slurry; molding the granular powder into a compact; and sintering the compact into a sinter.

According to an embodiment of the present invention, the step of preparing the slurry may include a first dispersion step of mixing the gallium oxide with a mixed solution of distilled water and a first dispersing agent, followed by wet milling; and a second dispersion step of forming the slurry by mixing a suspension produced by the first dispersion with a second dispersing agent and zinc oxide, followed by wet milling.

The first dispersion step may carry out the wet milling such that an average particle diameter of the gallium oxide ranges from 0.2 to 0.6 μm.

The first dispersion step may add the first dispersing agent at a content ranging, by weight, from 0.1 to 2 percent of the gallium oxide.

The second dispersion step may add the second dispersing agent at a content ranging, by weight, from 0.3 to 2.5 percent of the zinc oxide.

The second dispersion step may be controlled such that an average particle diameter of the slurry ranges from 0.1 to 0.5 μm.

The step of preparing the slurry may further include adding a binder into the slurry.

The step of sintering the compact may include sintering the compact at a temperature ranging from 1400 to 1600° C. under an air or oxygen atmosphere.

In a further another aspect of the present invention, provided is a thin-film transistor that includes an electrode, a barrier layer and an oxide semiconductor layer. The barrier layer is disposed between the electrode and the oxide semiconductor layer, and contains zinc oxide doped with gallium oxide, the content of the gallium oxide ranging, by weight, from 5 to 40 percent of the barrier layer.

According to embodiments of the present invention, it is possible to manufacture a high-density sputtering target that can be reliably subjected to DC sputtering by doping zinc oxide with gallium oxide.

In addition, during manufacturing of the TFT, when an oxide protective layer based on SiOₓ is deposited on the gate, source and drain electrodes which can be made of Cu using the sputtering target, it is possible to prevent CuOₓ from forming, thereby improving the contact characteristics between the Cu electrode and the protective layer. A barrier layer that is applicable to displays but has a high transmittance can be deposited on the Cu electrode, i.e. be formed between the Cu electrode and the oxide protective layer.

Furthermore, it is possible to deposit the barrier layer using the sputtering target. The barrier layer can be etched concurrently with the Cu electrode, and the etching speed can be easily adjusted, so that neither an undercut nor a tip is formed. The barrier layer does not create a problem due to the corrosion of the Cu electrode or the like. Accordingly, the barrier layer can help facilitate and simplify the TFT fabrication process. In other words, the barrier layer deposited using the sputtering target according to the invention does not require a separate patterning process and can be patterned together with the Cu electrode in the process of patterning the Cu electrode.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is an electron probe micro-analyzer (EPMA) image showing a sinter manufactured by a method of manufacturing a sputtering target according to an embodiment of the present invention;

FIG. 2A and FIG. 2B are graphs showing secondary ion mass spectrometer (SIMS) analysis results on the tendency of Cu depending on the presence of a barrier layer that is deposited using a sputtering target according to an embodiment of the present invention;

FIG. 3A and FIG. 3B are transmission electron microscopy (TEM) pictures taken in order to compare etching characteristics depending on the composition of a barrier layer;

FIG. 4A and FIG. 4B are pictures taken using an electron microscope in order to observe the influence of a barrier layer that is deposited using a sputtering target according to an embodiment of the present invention on the oxidation of Cu; and

FIG. 5A and FIG. 5B are pictures taken using an electron microscope in order to observe the influence of a comparative example, i.e. a barrier layer that is deposited using a sputtering target made of a Cu—Mn alloy, on the oxidation of Cu.

### DETAILED DESCRIPTION OF THE INVENTION

Reference will now be made in detail to a zinc oxide (ZnO)-based sputtering target, a method of manufacturing the same, and a thin-film transistor (TFT) having a barrier layer deposited using the same according to the present invention, embodiments of which are illustrated in the accompanying drawings and described below, so that a person having ordinary skill in the art to which the present invention relates can easily put the present invention into practice.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

The zinc oxide-based sputtering target according to an embodiment of the present invention is a target with which a zinc oxide-based barrier layer is deposited in the process of manufacturing a thin-film transistor that forms a component of a flat panel display to which a Cu electrode is applied. The zinc oxide-based barrier layer can prevent Cu that is used for gate, source and drain electrodes and metal lines from, for example, diffusing into an overlying oxide layer which serves as a protective layer or reacting with the oxide layer. At the same time, the zinc oxide-based barrier layer can be concurrently etched with Cu under existing etching conditions due to high transmittance. In addition, it is possible to easily adjust the etching speed so that neither an undercut nor a tip is formed.

The zinc oxide-based sputtering target includes a sinter and a backing plate.

The sinter contains zinc oxide doped with gallium oxide, the content of gallium oxide ranging, by weight, from 5 to 40 percent of zinc oxide. When gallium oxide is added below 5 percent by weight, the zinc oxide-based barrier layer that is deposited using the target has a low resistivity and is thus suitable to be used for a transparent conductive film. However, the etching speed is too fast during manufacturing of a TFT, and etching causes corrosion and tips due to undercutting. In contrast, when gallium oxide is added above 40 percent by weight, it is impossible to realize targets that can be subjected to direct current (DC) sputtering. More preferably, gallium oxide is added in the range from 15 to 30 percent by weight.

According to an embodiment of the present invention, gallium oxide is uniformly distributed in zinc oxide, and gallium oxide aggregates are distributed at a size of 1 μm or less in the sinter. Accordingly, since the sinter has a local resistance uniformity of 10% or less and a composition uniformity ranging from −10% to +10%, the same characteristics can be realized by a barrier layer that is deposited using the target. In addition, according to an embodiment of the present invention, the sinter can contain at least one selected from several group III elements, such as In and Al, and several group IV elements, such as Zr, Si and Sn.

The backing plate is a member that serves to support the sinter, and can be made of Cu, preferably, oxygen-free Cu, Ti or stainless steel that has superior electrical conductivity and thermal conductivity. The backing plate is bonded to the rear surface of the sinter using a bonding material made of, for example, In, thereby forming the zinc oxide-based sputtering target.

The zinc oxide-based sputtering target which includes the sinter and the backing plate has a resistivity of 100Ω·cm or less. In addition, the zinc oxide-based sputtering target according to an embodiment of the present invention has a high density of 5.3 g/cm³. Accordingly, the zinc oxide-based sputtering target is characterized in that the discharge can be stably conducted without abnormal discharge during DC sputtering when a high power density is applied, for example, when the power density is applied in the range from 0.1 to 8 W/cm². In addition, since the zinc oxide-based sputtering target according to an embodiment of the present invention has less blackening, which is typical of common sputtering targets, minimum defects are caused by particles in the sputtering deposition process. The zinc oxide-based sputtering target having these characteristics can be realized by controlling the manufacturing process, which will be described in more detail later in relation to the method of manufacturing a zinc oxide-based sputtering target.

As described above, the zinc oxide-based sputtering target according to an embodiment of the present invention is used for the deposition of a zinc oxide-based barrier layer of a TFT. The TFT includes a Cu layer which forms gate, source and drain electrodes and lines and an oxide layer, or a protective layer, which is deposited on the Cu layer. When an oxide layer made of, for example, SiOₓ is deposited on the Cu layer, the Cu in the Cu layer reacts with oxygen, forming CuOₓ. When CuOₓ is formed in the Cu reaction, the Cu layer discolors and the ability of the Cu layer to contact the oxide layer deteriorates, so that the oxide layer peels off or the characteristics of the TFT deteriorate. Therefore, during fabrication of the TFT, when the zinc oxide-based barrier layer is deposited on the Cu layer using the zinc oxide-based sputtering target according to an embodiment of the present invention, it is possible to reduce the reaction between the Cu layer and the oxide layer. Here, the barrier layer that is deposited using the zinc oxide-based sputtering target according to an embodiment of the present invention has a crystal size ranging from 10 to 5000 Å. In addition, the barrier layer can be deposited to a thickness ranging from 30 to 50 nm. In this case, the resistivity of the barrier layer ranges from 100 to 1×10⁻⁴Ω·cm. In order to realize these characteristics of the barrier layer, it is preferable that the barrier layer is deposited using the zinc oxide-based sputtering target according to an embodiment of the present invention and Ar gas and oxygen are mixed at a predetermined ratio during sputtering.

While the zinc oxide-based sputtering target according to an embodiment of the present invention can form a single phase barrier layer or a multi-phase barrier layer depending on the manufacturing conditions, a barrier layer that is basically composed of a hexagonal layered compound can be formed. The barrier layer that is deposited using the zinc oxide-based sputtering target is easily etched using a weak acid, since the crystal is oriented along the c-axis in the zinc oxide-based crystal structure. It is therefore possible to easily control the etching speed by adjusting the concentration of the etching solution and/or adjusting the composition of the target. Therefore, the barrier layer can be etched together with the Cu layer in a batch process using the existing etching solution that is used for etching the Cu solution without addition of a separate process. This can contribute to ease and simplification of the TFT fabrication process. Here, in order to improve the etching characteristics of the barrier layer, the deposited barrier layer can be heat-treated at a temperature ranging from 200 to 400° C. for 10 to 120 minutes.

A description will be given below of a method of manufacturing a zinc oxide-based sputtering target according to an embodiment of the present invention.

In order to realize all characteristics of the barrier layer that is deposited and formed using the above-described zinc oxide-based sputtering target according to an embodiment of the present invention, the manufacturing conditions for the zinc oxide-based sputtering target must be highly controlled For this, the method of manufacturing a zinc oxide-based sputtering target according to an embodiment of the present invention includes a slurry preparation step, a drying step, a molding step and a sintering step.

The slurry preparation step is the step of producing a slurry by adding gallium oxide to zinc oxide, the weight ratio of the gallium oxide ranging from 10 to 50 weight percent of the slurry. The slurry preparation step can be divided into a first dispersing step and a second dispersing step.

First, in the first dispersing step, gallium oxide is mixed to a mixed solution in which distilled water and a dispersing agent are mixed, wet milling is carried out such that the average diameter (size) of the dispersed particles ranges from 0.1 to 0.8 μm. The content of the dispersing agent that is added may range, by weight, from 0.1 to 2 percent of gallium oxide. Here, the dispersing agent must have a structure that can be easily absorbed on the surface of gallium oxide in the suspension produced by the wet milling and on the surface of zinc oxide that is to be added in the subsequent process. For this purpose, an organic acid, such as citric acid, a polycarboxylic acid, or the like can be used as the dispersing agent. The dispersing agent is required to maintain the pH of the suspension in order to realize the high dispersion characteristics of the zinc oxide particles and the gallium oxide particles. For this, a dispersing agent such as polycarboxylic acid salt, for example, polyacrylic acid ammonium salt, polycarboxylic acid amine salt, or the like can be used. In this fashion, the first dispersing step disperses gallium oxide.

Afterwards, in the second dispersing step, zinc oxide is added to the suspension in which gallium oxide is dispersed such that the weight ratio of gallium oxide ranges, by weight, from 5 to 40 percent, preferably, from 15 to 30 percent, and a dispersing agent is added to the resultant mixture such that the content of the dispersing agent ranges, by weight, from 0.3 to 2.5 percent of the zinc oxide, thereby producing a slurry. The slurry is wet-milled such that the average diameter of particles ranges from 0.1 to 0.5 μm. The amount of the dispersing agent to be added is closely correlated with the average particle diameter of the slurry. Specifically, when the dispersing conditions and the particle diameter ratio are not satisfied, zinc oxide and gallium oxide which have no electrical characteristics tend to cohere inside a sinter that is produced by the subsequent process, thereby significantly increasing the local resistance of the sinter. This result may hinder reliable DC sputtering of the zinc oxide-based sputtering target, or a final product, and have a severe adverse effect on the uniformity of the composition of a thin film that is deposited thereby. In addition, as in this embodiment of the present invention, adjustment of the dispersing particle diameters of gallium oxide and the slurry is closely related to a sintering temperature. When the dispersing particle diameters are not controlled in the above-mentioned range, the zinc oxide may be caused to abnormally volatilize during hot sintering.

When the second dispersing step is finished, a binder is added to the resultant slurry. The binder is added in order to maintain the strength of a compact in the process of molding the slurry after drying the slurry into a powder. The binder can be implemented as polyvinyl alcohol, poly ethylene glycol or the like. The binder can be added at a content ranging, by weight, from 0.01 to 5 percent, and preferably, from 0.5 to 3 percent of each of the gallium oxide and the zinc oxide powder in the slurry. The amount of the added binder has a great effect on the sintering density of the sinter. When the amount of the added binder is beyond this range, the molding density decreases in the process of molding the granular powder, leading to a decrease in the sintering density. The decreased sintering density means that pores which cause local high resistances are formed inside the sinter. This also acts as a hindering factor in the manufacture of the zinc oxide-based sputtering target that can be subjected to DC sputtering.

The reason why the wet milling is carried out in the stepwise fashion as in this embodiment of the present invention is as follows. Since the dried raw powders have different average particle diameters as well as different levels of hardness and cohesion, it is difficult to control each raw material powder with an intended particle diameter when these substances of dried raw powder are mixed together and are summarily wet-milled. Then, during manufacturing of the sinter, gallium oxide does not uniformly diffuse across a zinc oxide matrix and localized clustering occurs, thereby deteriorating the electrical characteristics and mechanical properties of the target. Therefore, in order to overcome this problem, the slurry preparation step is carried out in a stepwise fashion by sequentially inputting the impurity into a water system so as to be uniformly dispersed with an intended particle diameter, followed by finally adding zinc oxide into the resultant mixture, such that the zinc oxide can be dispersed and the gallium oxide can be uniformly mixed with the zinc oxide. That is, the slurry preparation step is divided into the first dispersing step and the second dispersing step.

The subsequent drying step is the step of forming a granular powder by drying the slurry. In this step, it is possible to produce the granular powder by drying the slurry by a spray drying method.

Next, the molding step is the step of molding the granular powder into a compact. This step makes the granular power into the compact using a cold press (a hydraulic press) and by cold isostatic pressing (CIP).

The next sintering step is the step of sintering the compact into a sinter. The sintering step sinters the compact at a temperature from 1400 to 1600° C. in an air or oxygen atmosphere. The sintering temperature as mentioned above refers to a temperature where the resistance of the target is controlled in the range from 1×10⁻³ to 50Ω where DC sputtering can be used in the process of manufacturing a gallium oxide-doped zinc oxide-based target. The sintering step like this can be carried out such that it leads to a high density and a low resistance.

Finally, when the sinter that is produced in this fashion is bonded to the backing plate, the manufacturing of the zinc oxide-based sputtering target according to an embodiment of the present invention is completed. The resistivity of the zinc oxide-based sputtering target that is manufactured according to an embodiment of the present invention is 100Ω·cm or less, such that a barrier layer can be reliably formed on the Cu layer when fabricating a TFT by DC sputtering. The power density of DC sputtering that is induced when forming the barrier layer can be adjusted freely in the range from 0.1 to 8 W/cm². Although glow discharge is possible beyond this range, there are a high possibility that defects such as abnormal discharge may occur and a very high possibility that cracks may be formed in the target. Therefore, it is not applicable to the industry beyond this range.

When the thin film, i.e. the barrier layer, is deposited by DC sputtering using the zinc oxide-based sputtering target that is manufactured according to an embodiment of the present invention, the resistivity of the barrier layer can range from 100 to 1×10⁻⁴Ω·cm at a thickness of 30 nm depending on the composition. When the barrier layer is deposited using the zinc oxide-based sputtering target, the basic degree of vacuum of the chamber must be controlled in the range from 1×10⁻⁷ to 1×10⁻⁵ torrs. Although a higher-quality thin film can be produced as the initial degree of vacuum is higher, maintaining an ultra-high vacuum level in industrial facilities leads to increased cost. Therefore, when the degree of vacuum is maintained at the above-mentioned level, a high-quality barrier layer can be produced using the zinc oxide-based sputtering target that is manufactured according to an embodiment of the present invention. In addition, a reactive gas such as oxygen can be fed together with Ar gas in order to control the crystallinity and resistance of the barrier layer during deposition. After being deposited as above, the barrier layer can be heat-treated at a temperature ranging from 200 to 400° C.

In the barrier layer that is deposited or heat-treated as described above using the zinc oxide-based sputtering target that is manufactured according to an embodiment of the present invention, during TFT processing, neither an undercut nor a tip is formed between the lower layer and the upper film layer when etched using a chemical that is used for etching the Cu layer. When the etching speed is too slow, mass productivity is lowered. In contrast, when the etching speed is too fast, it is difficult to control the process. When the barrier layer is etched after being formed using the zinc oxide-based sputtering target according to an embodiment of the present invention, etching can be controlled at a suitable speed. This can consequently prevent the problem due to nonuniform etching.

### Example 1

Gallium oxide having an average particle diameter of 4 μm was added at a content of 20 weight percent of a sputtering target to distilled water to which a dispersing agent was added at a content of 1.0 weight percent of the gallium oxide. The resultant mixture was ground/dispersed by wet milling such that the average diameter of dispersed particles became 0.3 μm. After that, indium oxide having an average particle diameter of 0.5 μm and a dispersing agent having a content of 0.5 weight percent of the zinc oxide were added, and the resultant mixture was wet-milled such that the final diameter of dispersed particles became 0.2 μm. The dispersing agent that was used here is polyacrylic acid amine salt. After the final zinc oxide-based slurry mixture was produced, 1.0 weight percent of polyvinyl acetate (PVA) and 0.5 weight percent of polyethylene glycol (PEG) were added as a binder. Milling was carried out once again, thereby producing a uniform slurry. Afterwards, the slurry was made into a granular powder by a spray drying method, and the granular powder was compressed using an axial press, followed by cold isostatic pressing.

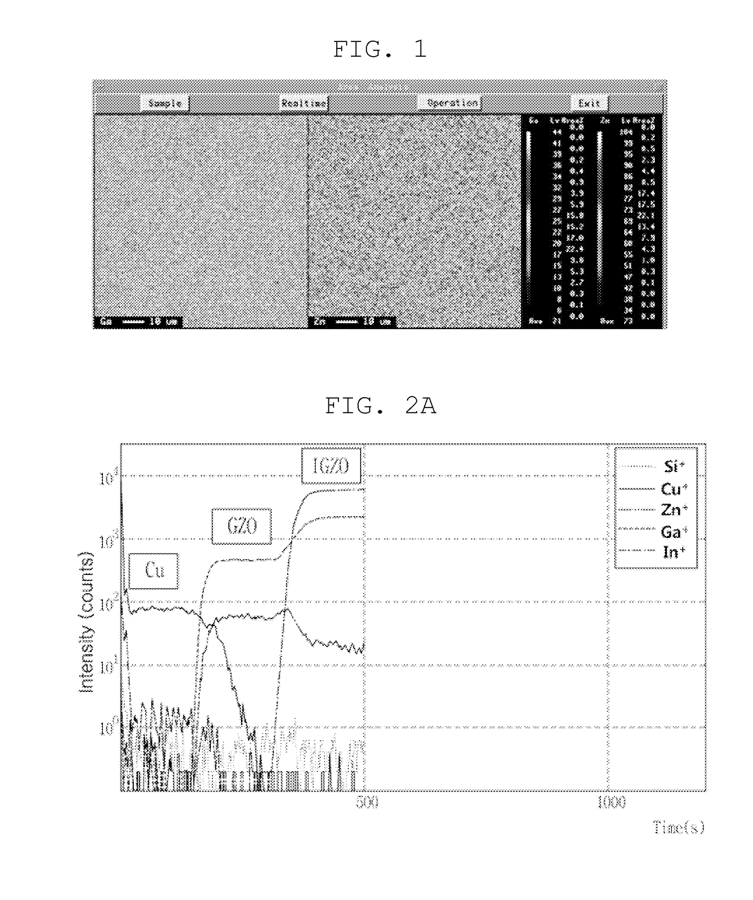

In sequence, the resultant compact was sintered at 1550° C. for 15 hours in an air or oxygen atmosphere. When the sintering was finished, the resistivity of the sinter was 5.0×10⁻³Ω·cm, and the sintering density was 5.67 g/cm³. Gallium oxide aggregates distributed inside the zinc oxide of the manufactured sinter were examined by an electron probe micro-analyzer (EPMA) analysis, and the results are presented in FIG. 1. Referring to FIG. 1, it can be appreciated that all of the gallium oxide particles distributed inside the zinc oxide matrix are uniformly dispersed with a size of 1 μm or less.

### Example 2

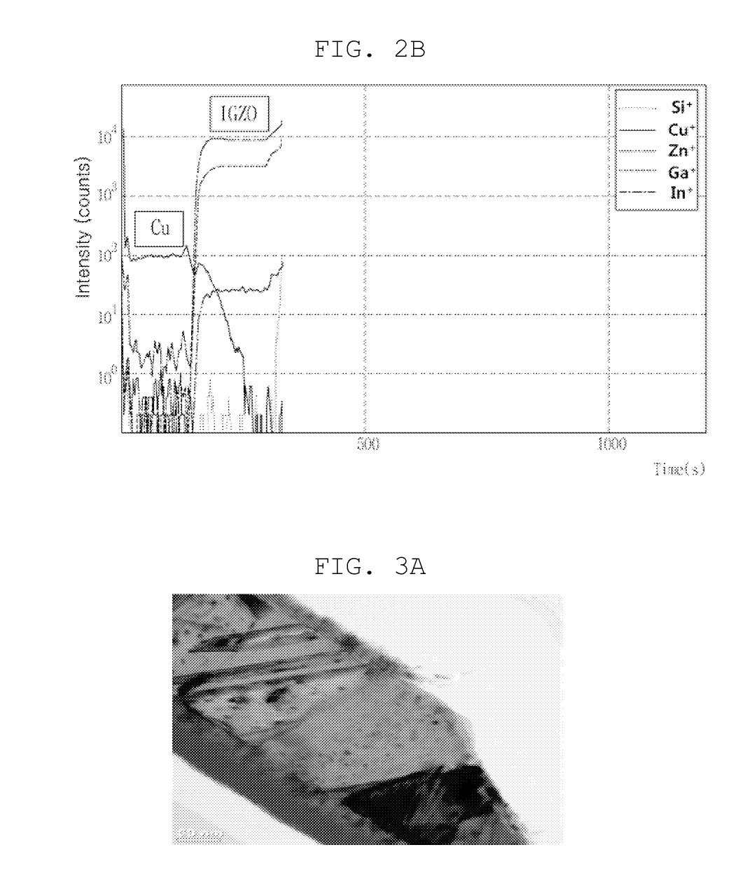

The sinter manufactured according to Example 1 was bonded to a backing plate made of Cu, and sputtering was carried out using the resultant structure. The sputtering conditions were controlled such that the base pressure of the chamber was 1×10⁻⁶ torr and the working pressure was 0.5 Pa. Deposition was enabled by causing plasma discharge at 100° C. in a pure Ar atmosphere. Here, the target size was 565 mm×690 mm, and the induced power was DC 10 kW. A resultant thin film was deposited to a thickness of 30 nm on a substrate. The substrate on which the thin film was deposited was a glass substrate that includes a piece of non-alkaline glass and an indium gallium zinc oxide (IGZO) layer which was formed on the glass in advance. Sample (a) was prepared by depositing Cu, or an electrode material, on the gallium-doped zinc oxide (GZO) thin film which was deposited at the 30 nm thickness on the IGZO layer, whereas Sample (b) was prepared by depositing Cu on the IGZO layer. A secondary ion mass spectrometer (SIMS) analyses was conducted on whether or not Cu diffuses into the IGZO layer, and the results are presented in FIG. 2A and FIG. 2B. Referring to FIG. 2A, it can be appreciated that the Cu diffusion was prevented by the gallium-doped zinc oxide (GZO) thin film. In contrast, referring to FIG. 2B, it can be appreciated that the Cu component diffused into the IGZO layer when Cu was deposited on the pure IGZO layer.

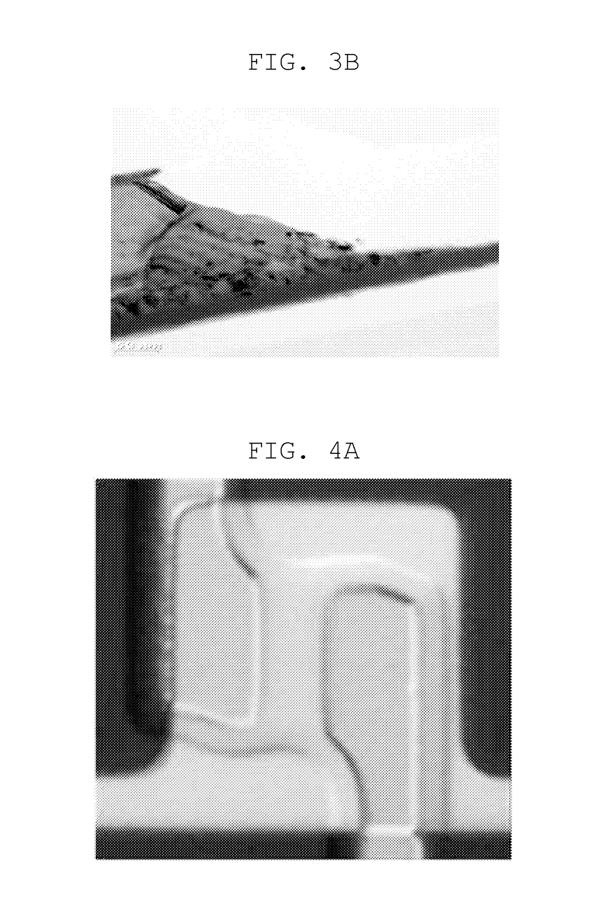

In addition, as for the TFT structure, in order to examine whether or not the barrier layer that is deposited using the sputtering target according to the present invention acts as a protective layer for Cu when a SiOₓ layer is deposited on source and drain electrodes, Sample (a) and Sample (b) were prepared using a substrate which includes a piece of non-alkaline glass and a Cu layer deposited on the glass. Sample (a) was prepared by depositing a gallium oxide-doped zinc oxide (GZO) thin film on the substrate using the sputtering target according to the present invention and then depositing a SiOₓ thin film by chemical vapor deposition (CVD), whereas Sample (b) was prepared by depositing an indium oxide-doped zinc oxide (IZO) thin film on the substrate and then depositing a SiOₓ thin film by CVD. Sample (a) and Sample (b) were etched using a Cu etching solution. A transmission electron microscopy (TEM) analysis was conducted on whether or not the residue was left, and the results were presented in FIG. 3A and FIG. 3B. Referring to FIG. 3A and FIG. 3B, it can be appreciated that the residue was left only in the comparative example of FIG. 3B.

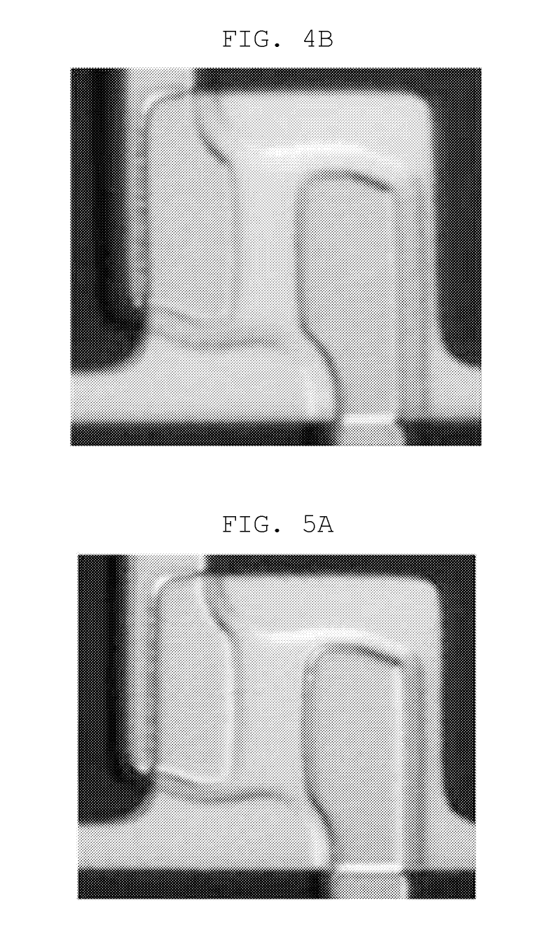

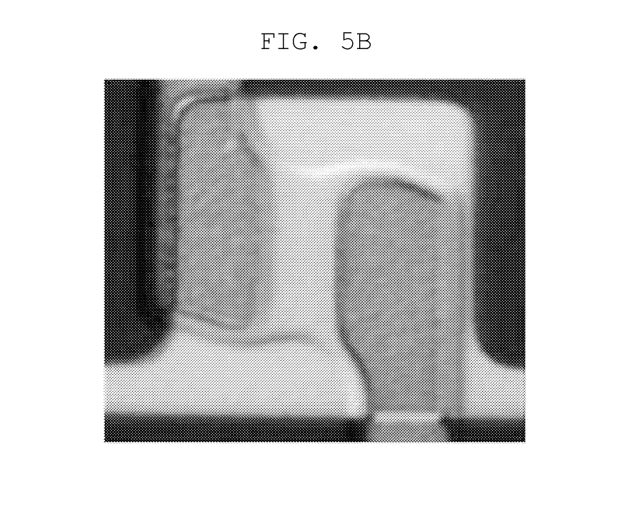

FIG. 4A, FIG. 4B, FIG. 5A and FIG. 5B are pictures showing the results of observation on whether or not CuOₓ is formed when a material for a barrier layer on a Cu electrode is changed, in which FIG. 4A and FIG. 4B show the states before and after a SiOₓ thin film is deposited on a barrier layer after the barrier layer is deposited on the Cu electrode using the sputtering target according to the present invention, and FIG. 5A and FIG. 5B show the states before and after a SiOₓ thin film is deposited on a barrier layer after the barrier layer is deposited on the Cu electrode using a Cu—Mn target. Comparing FIG. 4A and FIG. 4B, there are no changes before and after the deposition of the SiOₓ thin film. In contrast, comparing FIG. 5A and FIG. 5B, it can be appreciated that the device has a change before and after the deposition of the SiOₓ thin film. In other words, when the gallium oxide-doped zinc oxide-based barrier layer is formed on the Cu electrode using the sputtering target according to the present invention, even though the SiOₓ thin film is formed, the reaction between the Cu electrode and the SiOₓ thin film is reduced by the barrier layer. In contrast, when the Cu—Mn barrier layer is formed on the Cu electrode, this barrier layer does not help reduce the reaction between the Cu electrode and the SiOₓ thin film, so that CuOₓ is formed due to the reaction between Cu and SiOₓ. This consequently deteriorates the contact characteristics between the Cu electrode and the SiOₓ thin film and thus the TFT characteristics.

The foregoing descriptions of specific exemplary embodiments of the present invention have been presented with respect to the drawings. They are not intended to be exhaustive or to limit the present invention to the precise forms disclosed, and obviously many modifications and variations are possible for a person having ordinary skill in the art in light of the above teachings.

It is intended therefore that the scope of the present invention not be limited to the foregoing embodiments, but be defined by the Claims appended hereto and their equivalents.

What is claimed is:

1. A zinc oxide-based sputtering target comprising:
a sinter comprising zinc oxide doped with gallium oxide, a content of the gallium oxide ranging, by weight, from 10 to 50 percent of the sinter; and
a backing plate bonded to a rear surface of the sinter to support the sinter.

2. The zinc oxide-based sputtering target of claim 1, wherein a resistivity of the sputtering target is 100Ω·cm or less.

3. The zinc oxide-based sputtering target of claim 2, the sputtering target being available for direct current sputtering.

4. The zinc oxide-based sputtering target of claim 6, wherein a power density that is applied during the direct current sputtering ranges from 0.1 to 8 W/cm².

5. The zinc oxide-based sputtering target of claim 1, wherein a density of the sputtering target is 5.3 g/cm³ or greater.

6. The zinc oxide-based sputtering target of claim 1, wherein aggregates of the gallium oxide are distributed at a size of 1 μm or less inside the sinter.

7. The zinc oxide-based sputtering target of claim 1, wherein the sinter comprises at least one selected from group III elements and group IV elements.

8. A method of manufacturing a thin-film transistor which includes an electrode and an oxide semiconductor layer, the method comprising depositing a barrier layer between the electrode and the oxide semiconductor layer using the zinc oxide-based sputtering target as recited in claim 1.

9. The method of claim 8, wherein the barrier layer has a crystal size ranging from 10 to 5000 Å.

10. The method of claim 8, wherein the barrier layer is deposited to a thickness ranging from 30 to 50 nm.

11. The method of claim 10, wherein a resistivity of the barrier layer ranges from 100 to 1×10⁻⁴Ω·cm.

12. The method of claim 8, wherein the electrode comprises Cu.

13. A method of manufacturing a zinc oxide-based sputtering target, comprising:
preparing a slurry by adding gallium oxide to zinc oxide, a content of the gallium oxide ranging, by weight, from 10 to 50 percent of the slurry;
forming a granular powder by drying the slurry;
molding the granular powder into a compact; and
sintering the compact into a sinter.

14. The method of claim 13, wherein preparing the slurry comprises:
first dispersion of mixing the gallium oxide with a mixed solution of distilled water and a first dispersing agent, followed by wet milling; and
second dispersion of forming the slurry by mixing a suspension produced by the first dispersion with a second dispersing agent and zinc oxide, followed by wet milling.

15. The method of claim 14, wherein the first dispersion comprises carrying out the wet milling such that an average particle diameter of the gallium oxide ranges from 0.2 to 0.6 μm.

16. The method of claim 14, wherein the first dispersion comprises adding the first dispersing agent at a content ranging, by weight, from 0.1 to 2 percent of the gallium oxide.

17. The method of claim 14, wherein the second dispersion comprises adding the second dispersing agent at a content ranging, by weight, from 0.3 to 2.5 percent of the zinc oxide.

18. The method of claim 14, wherein the second dispersion is controlled such that an average particle diameter of the slurry ranges from 0.1 to 0.5 μm.

19. The method of claim 14, wherein preparing the slurry further comprises adding a binder into the slurry.

20. The method of claim 13, wherein sintering the compact comprises sintering the compact at a temperature ranging from 1400 to 1600° C. under an air or oxygen atmosphere.

21. A thin-film transistor comprising an electrode, a barrier layer and an oxide semiconductor layer, wherein the barrier layer is disposed between the electrode and the oxide semiconductor layer, and comprises zinc oxide doped with gallium oxide, a content of the gallium oxide ranging, by weight, from 5 to 40 percent of the barrier layer.
